(19) United States
(12) Patent Application Publication
(10) Pub. No.: US 2025/0006681 A1
(43) Pub. Date: Jan. 2, 2025

(54) UNIFIED CRACKSTOP STRUCTURE FOR JOINING SEMICONDUCTOR BUILDS

(71) Applicant: International Business Machines Corporation, Armonk, NY (US)

(72) Inventors: Nicholas Alexander POLOMOFF, Hopewell Junction, NY (US); Katsuyuki Sakuma, Fishkill, NY (US); Akihiro Horibe, Yokohama-shi (JP); Takahito Watanabe, Yokohama (JP); John Lucas Darling, Delmar, NY (US); Promod Roy Chowdhury, Guilderland, NY (US); Keodara Seifert, Cohoes, NY (US)

(21) Appl. No.: 18/216,404

(22) Filed: Jun. 29, 2023

(51) Int. Cl. H01L 23/00; H01L 23/498

(52) U.S. Cl. CPC H01L 24/14; H01L 23/49838; H01L 23/562; H01L 24/05; H01L 24/06; H01L 24/11; H01L 24/13; H01L 24/16; H01L 24/32; H01L 24/73; H01L 24/81; H01L 2224/05557; H01L 2224/05571; H01L 2224/0603; H01L 2224/06051; H01L 2224/11462; H01L 2224/11849; H01L 2224/13011; H01L 2224/13021; H01L 2224/1403; H01L 2224/14051; H01L 2224/16147; H01L 2224/16227; H01L 2224/16237; H01L 2224/32145; H01L 2224/32225; H01L 2224/73204; H01L 2224/81203; H01L 2224/81815

(57) ABSTRACT

A unified crackstop structure is described incorporating at least two semiconductor builds, each having a crackstop structure on its periphery and a metal wall or line extending from one crackstop structure to the other.

### BACKGROUND

The present invention relates generally to the electrical, electronic and computer arts and, more particularly, to joining two semiconductor builds such as chips, dies, wafers, interposers, or combinations thereof together and, more particularly, to structures that prevent moisture ingress as well as block or minimize external or internal crack growth or propagation originating primarily from dicing wafers and delamination and warpage from chip package interaction (CPI) related issues or threats, and the like.

In 2.5 and 3D packaging, two or more semiconductor builds may be joined together by thermal compression bonding, with each respective semiconductor build having respective metal based crackstop structures built in the back end of line (BEOL) dielectric stack layers. Thermal compression bonding is a semiconductor package joining technique that connects two or more semiconductor based builds through the use of solder bumps but inadvertently leaves a gap between the semiconductor builds at the edges where the crackstop structures are located. In the gap, with or without underfill, cracks can form in either semiconductor build; the cracks can separate the two bonded semiconductor builds or provide an entry point for cracks to bypass the crackstop structures and have direct access into the active device regions of the respective semiconductor builds and therefore could potentially rip/pull apart portions of the two adjoined semiconductor builds resulting in catastrophic failure of the semiconductor package assembly. The terms ‘2.5D’ and ‘3D’ are used herein in their normal sense as will be familiar to the skilled artisan; namely, they refer to packaging methodologies for including multiple integrated circuits in the same package. In a 2.5D structure, two or more active semiconductor chips are placed side-by-side on a silicon interposer or substrate to obtain high die-to-die interconnect density. In a 3D structure, active chips are integrated by die stacking to provide short interconnects and a small package footprint.

### BRIEF SUMMARY

Principles of the invention provide techniques for a unified crackstop structure for joining semiconductor builds. In one aspect, an exemplary semiconductor structure includes a first semiconductor build having a first crackstop structure along a first periphery of the first semiconductor build, a second semiconductor build having a first crackstop structure along a first periphery of the second semiconductor build, and a metal line bonded to the first crackstop structure of the first semiconductor build and the first crackstop structure of the second semiconductor build to form a wall between and along a portion of the first peripheries of the first and second semiconductor build such that the crackstop structures are joined together by the metal line.

In another aspect, an exemplary method for joining two semiconductor builds includes the steps of selecting two semiconductor builds, each having a crackstop structure on a periphery thereof, forming a metal line adjoining a corresponding one of the crackstop structures on one of the semiconductor builds, aligning the metal line over the crackstop structure of the other semiconductor build, and bonding the metal line to the other semiconductor build such that the two semiconductor builds form a rigid structure to resist external and internal crack nucleation or growth, delamination and warpage resulting from external energies and other CPI-related threats.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Preventing/blocking external cracks in semiconductor structures formed from multiple semiconductor builds;
Holding dies or other semiconductor builds together preventing internal cracking/delamination from occurring;
Enhancing rigidity of semiconductor structures by preventing shear tearing apart the C4 (controlled collapse of chip connection) structures;
Enhancing rigidity/strength by preventing pull-apart/tensile disruption.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 shows a cross-section view of one embodiment of the invention.

FIG. 2 shows a cross-section view of a defective semiconductor build of the prior art showing a warped silicon interposer.

FIGS. 3A-3F show cross-section views of various metal landing pads.

FIG. 4 shows an enlarged three-dimensional view of a metal line, landing pads, contact pads and C4 solder bumps on a chip.

FIG. 5 shows a three-dimensional view of a partially separated second embodiment of the invention.

FIGS. 6A-6C shows an enlarged cross-section view of two crackstop structures, two landing pads and two metal lines on one semiconductor build in alignment and compressively joined to two crackstop structures on a second semiconductor build.

FIG. 7A is a top view showing the outline on a chip having two crackstop structures and four bump pads underneath a seed layer.

FIG. 7B shows a cross-section view along the lines 7B-7B showing the upper layers of a chip.

FIG. 8A is a top view as shown in FIG. 7A with a photoresist layer on the top surface.

FIG. 8B is a cross-section view of FIG. 8A along the lines 8B-8B.

FIG. 9A is a top view as shown in FIG. 8A with the photoresist patterned and developed.

FIG. 9B is a cross-section view of FIG. 9A along the lines 9B-9B.

FIG. 10A is a top view as shown in FIG. 9A after solder has been electroplated where the seed layer is exposed.

FIG. 10B is a cross-section view of FIG. 10A along the lines 10B-10B.

FIG. 11A is a top view as shown in FIG. 10A after the photoresist has been removed.

FIG. 11B is a cross-section view of FIG. 11A along the lines 11B-11B showing the solder.

FIG. 12A is a top view as shown in FIG. 11A showing the two metal lines and solder bumps after metal reflow.

FIG. 12B is a cross-section view of FIG. 12A along the lines 12B-12B after metal reflow.

FIG. 13A is a top view as shown in FIG. 8A with the photoresist patterned and developed.

FIG. 13B is a cross-section view of FIG. 13A along the lines 13B-13B.

FIG. 14A is a top view as shown in FIG. 13A except solder has been electroplated where the seed layer is exposed.

FIG. 14B is a cross-section view of FIG. 14A along the lines 14B-14B.

FIG. 15A is a top view as shown in FIG. 14A after the patterned photoresist has been removed.

FIG. 15B is a cross-section view of FIG. 15A along the lines 15B-15B showing the solder remaining after the photo resist is removed.

FIG. 16A is a top view as shown in FIG. 15A showing two arrays of metal bumps for the two metal lines and the solder bumps after metal reflow.

FIG. 16B is a cross-section view of FIG. 16A along the lines 16B-16B after metal reflow.

FIG. 17 is a cross-section view of the upper layers of metal of two semiconductor builds aligned face to face prior to joining the semiconductor builds.

FIG. 18 is a cross-section view of the two semiconductor builds as shown in FIG. 17 joined under pressure.

FIG. 19 is a cross-section view of a second embodiment of the invention showing two semiconductor builds joined by two metal lines formed by metal reflow of two arrays of solder bumps.

FIG. 20A is a top view of one internal surface of two joined semiconductor builds having two continuous unified crackstop structures, not shown, wherein the two continuous peripheral metal lines seal or wall off the underfill.

FIGS. 20B-20C are top views of one internal surface of two joined semiconductor builds being filled with an underfill dielectric with two unified crackstop structures, not shown, wherein the one or two peripheral metal lines have openings therein.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

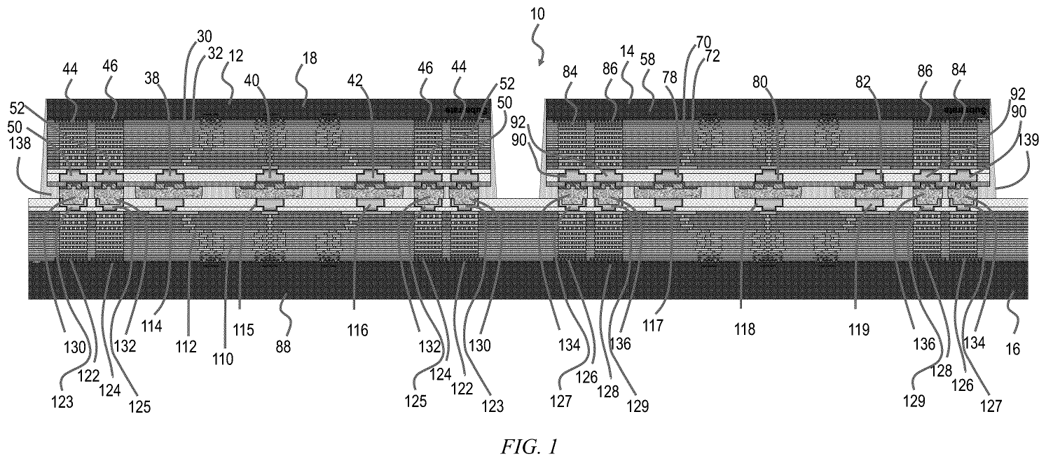

Referring now to the drawing, FIG. 1 shows a cross section view of semiconductor structure 10 comprising semiconductor builds 12, 14, and 16. Semiconductor build 12 includes a silicon substrate 18 which has devices therein not shown and device contacts not separately numbered. Interconnect layers 30 interconnect the devices with metal wiring 32 to the device contacts and to contact pads 38, 40 and 42. Crackstop structures 44 and 46 are built at the same time interconnect layer 30 is formed and include landing pads 50 and 52 above crackstop structures 44 and 46. Crackstop structures 44 and 46 follows a periphery path around the perimeter of silicon substrate 18. Landing pads 50 and 52 likewise are above respective crackstop structures 44 and 46 and follows the periphery around silicon substrate 18.

Semiconductor build 14 has the same structure as semiconductor build 12. Semiconductor 14 has silicon substrate 58, an interconnect layers 70, and metal wiring 72. Semiconductor build 14 has contact pads 78, 80 and 82, and crackstop structures 84 and 86 and respective landing pads 90 and 92 positioned above crackstop structures 84 and 86 at the surface of substrate 58. Semiconductor builds 12 and 14 are positioned to interconnect contact pads 38, 40, 42, 78, 80, and 82 to contact pads 114-119 of semiconductor build 16.

Semiconductor build 16 has a silicon substrate 88, an interconnection layer 110, metal wiring 112, contact pads 114-119 and crackstop structures 122, 124, 126 and 128 and have respective landing pads 123, 125, 127 and 129. Semiconductor build 16 is aligned with respective crackstop structures on semiconductor build 12 and semiconductor build 14 wherein metal lines 130, 132, 134 and 136 are formed by thermal compression bonding semiconductor build 12 and semiconductor build 14 to semiconductor build 16. At the same time contact pads of semiconductor build 12 and 16 are joined by solder bumps positioned on one semiconductor build being compressed against and bonded to the contact pads of the other.

As shown in FIG. 1, Metal line 130 along with landing pads 50 and 123 provide a unified crackstop with a continuous metal wall from crackstops 44 of semiconductor build 12 to crackstops 122 of semiconductor build 16. Metal line 132 along with landing pads 52 and 125 provide a unified crackstop structure with a continuous metal wall from crackstop structure 46 of semiconductor build 12 to crackstop structure 124 of semiconductor build 16. Metal line 134 along with landing pads 90 and 127 provide a unified crackstop structure with a continuous metal wall from crackstop structure 84 of semiconductor build 14 to crackstop 126 of semiconductor build 16. Metal line 136 along with landing pads 92 and 129 provide a unified crackstop structure with a continuous metal wall from crackstop structure 86 of semiconductor build 14 to crackstop structure 128 of semiconductor build 16. Metal lines 130, 132, 134 and 136 may include, for example, lead tin solder. While two unified crackstop structure 130 and 132 are shown in FIG. 1 on the periphery of semiconductor builds 12 and 14, one unified crackstop structure may be used for simplicity but potentially with a higher risk of cracks propagating into the active or device area of the semiconductor build. An underfill 138 may be inserted into the space between semiconductor builds 12 and 16 and underfill 139 may be inserted into the space between semiconductor builds 14 and 16.

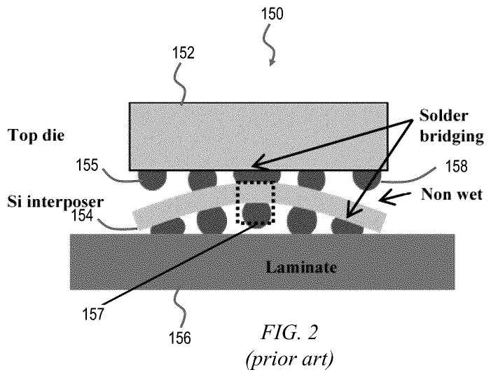

FIG. 2 is a cross section view showing a defective semiconductor structure 150 comprising semiconductor build 152 over a silicon interposer 154 positioned over a laminate 156 to form a semiconductor structure. Solder bumps or C4 bumps are shown making interconnections between semiconductor build 152 and silicon interposer 154 and between silicon interposer 154 and laminate 156. Silicon interposer 154 is shown warped into an arc profile causing solder bumps 155 and 158 to separate at the ends of silicon interposer 154 and solder bump 157 to separate in the middle of interposer 154 due to its' deformation or warping. The terms ‘2.5D’ and ‘3D’ are used herein in their normal sense as will be familiar to the skilled artisan; namely, they refer to packaging methodologies for including multiple integrated circuits in the same package. In a 2.5D structure, two or more active semiconductor chips are placed side-by-side on a silicon interposer to obtain high die-to-die interconnect density. In a 3D structure, active chips are integrated by die stacking to provide short interconnects and a small package footprint.

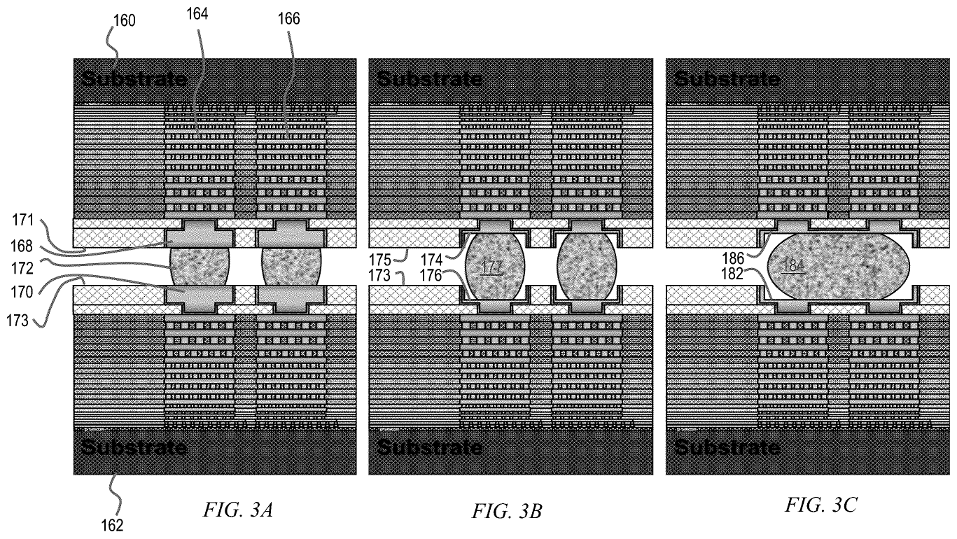

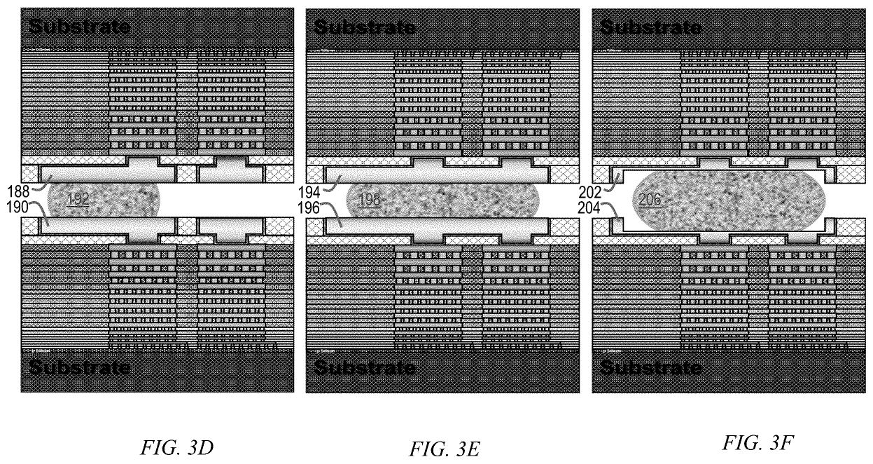

FIGS. 3A-3F are cross section views of unified crackstop structures having different landing pad shapes affecting the shape of the metal line formed along with other factors such as spacing between landing pads, quantity of solder and the surface tension of the solder. FIG. 3A shows semiconductor builds 160 and 162 having unified crackstop structures 164 and 166. Unified crackstop structure 164 has landing pads 168 and 170 and metal line 172 there between. Landing pads 168 and 170 have a flat surface and are flush with the surrounding surfaces 171 and 173. Unified crackstop structure 166 is the same as crackstop structure 164. FIG. 3B is similar to FIG. 3A except landing pads 174 and 176 are recessed below the surrounding surfaces 173 and 175 and allow a larger volume of metal and allows for a taller metal line 177. FIG. 3C is similar to FIG. 3B except in FIG. 3C landing pads 180 and 182 extend laterally from unified crackstop structure 164 to 166 (as numbered in FIG. 3A) forming one metal line 184 with a larger volume of solder.

FIG. 3D is similar to FIG. 3A except landing pads 188 and 190 of unified crackstop structure 164 (as numbered in FIG. 3A) extends laterally outward away from beneath the crackstop structure 164 towards the edges of semiconductor builds 160 and 162. Metal line 192 is wider than unified crackstop structure 164 of FIG. 3A. FIG. 3E is similar to FIG. 3D except landing pads 194 and 196 extend from unified crackstop structure 164 to 166 (as numbered in FIG. 3A) forming one metal line 198 with a larger volume of solder. FIG. 3F is similar to FIG. 3E except in FIG. 3F landing pads 202 and 204 extend laterally from unified crackstop structure 164 to 166 (as numbered in FIG. 3A) forming one metal line 206 with a larger volume of solder. It is worth noting that the top landing pads of the crackstops could be, for example, copper, aluminum, or the like.

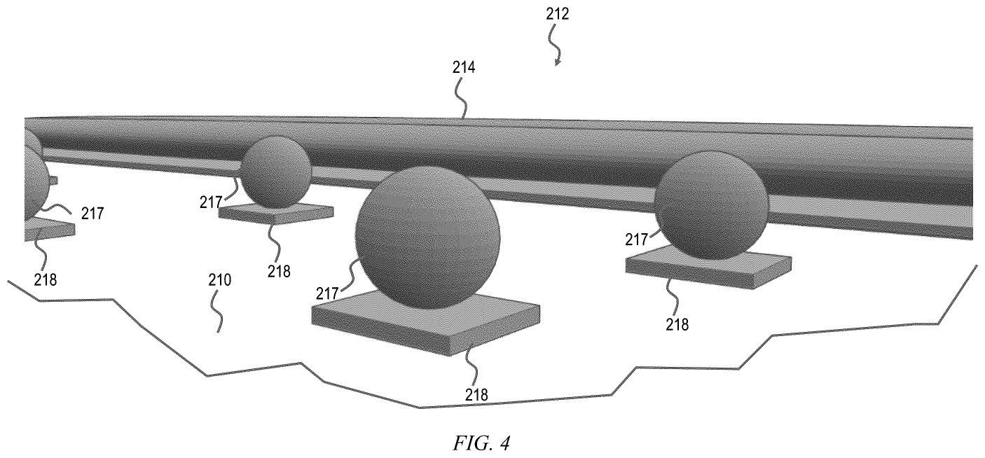

FIG. 4 shows a portion of the upper surface 210 of a semiconductor build 212 in a three dimensional view. Metal line 214 is positioned on landing pad 216. Solder balls 217 are shown spaced apart on contact pads 218.

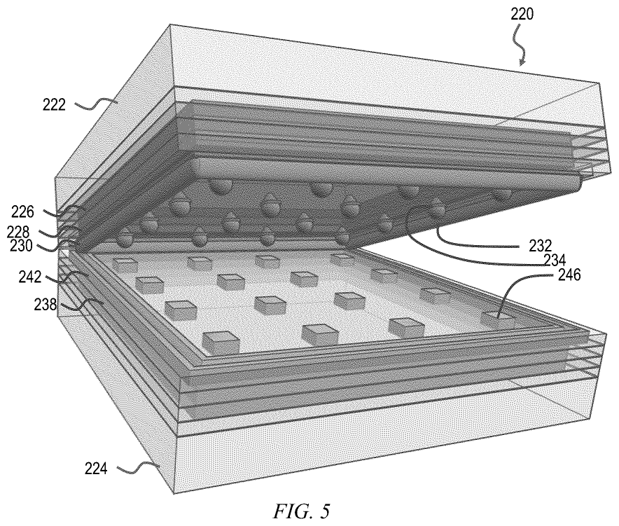

FIG. 5 shows a three dimensional view of a partially separated embodiment of the invention. Semiconductor structure 220 comprises semiconductor builds 222 and 224. Semiconductor build 222 has crackstop structure 226 on the periphery of the semiconductor build 222. Above crackstop structure 226 is landing pad 228 and metal line 230. Interior of metal line 230 are solder bumps 232 on contact pads 234.

Semiconductor build 224 has crackstop structure 238 on the periphery of the semiconductor build 224. Above crackstop structure 238 is landing pad 242 positioned to receive metal line 230 when semiconductor build 222 is aligned and thermal compression bonded to semiconductor build 224. Interior of metal line 244 are contact pads 246 positioned to receive solder bumps 232 during the step of bonding.

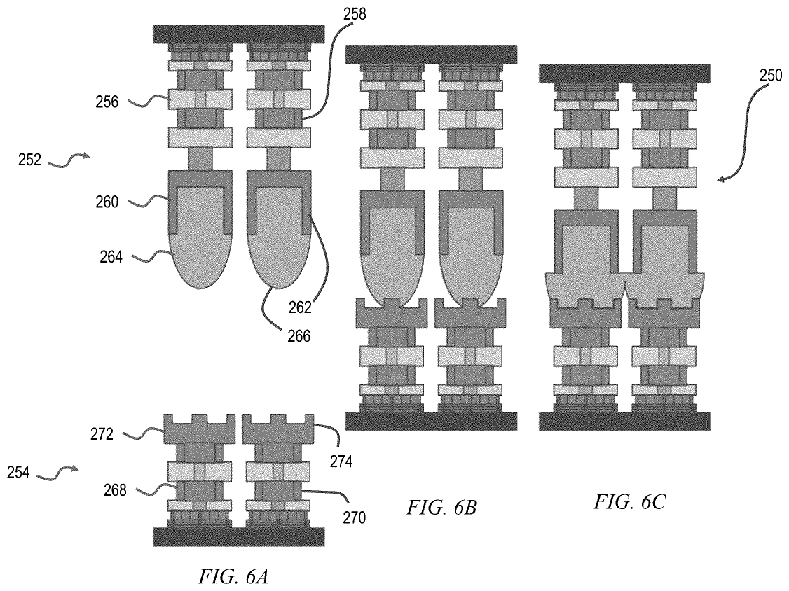

FIGS. 6A-6C are enlarged cross-section views showing the formation of unified crackstop structure 250 without showing other portions of the semiconductor builds 252 and 254. As shown in FIG. 6A, semiconductor build 252 has two parallel crackstop structures 256 and 258, two landing pads 260 and 262 thereon and two solder lines 264 and 266. Semiconductor build 254 has two corresponding parallel crackstop structures 268 and 270 and two landing pads 272 and 274 thereon. FIG. 6B is similar to FIG. 6A except solder lines 264 and 266 (as numbered in FIG. 6A) are positioned over and in initial contact with landing pads 272 and 274 (as numbered in FIG. 6A) respectively. FIG. 6C shows semiconductor builds 252 and 254 (as numbered in FIG. 6A) joined together by compressing the solder lines 264 and 266 (as numbered in FIG. 6A) to form unified crackstop structure 250. As shown in FIG. 6C, solder lines 264 and 266 are electrically and mechanically joined due to solder deformation during compression or bonding of solder lines 264 and 266 and the spacing of the landing pads.

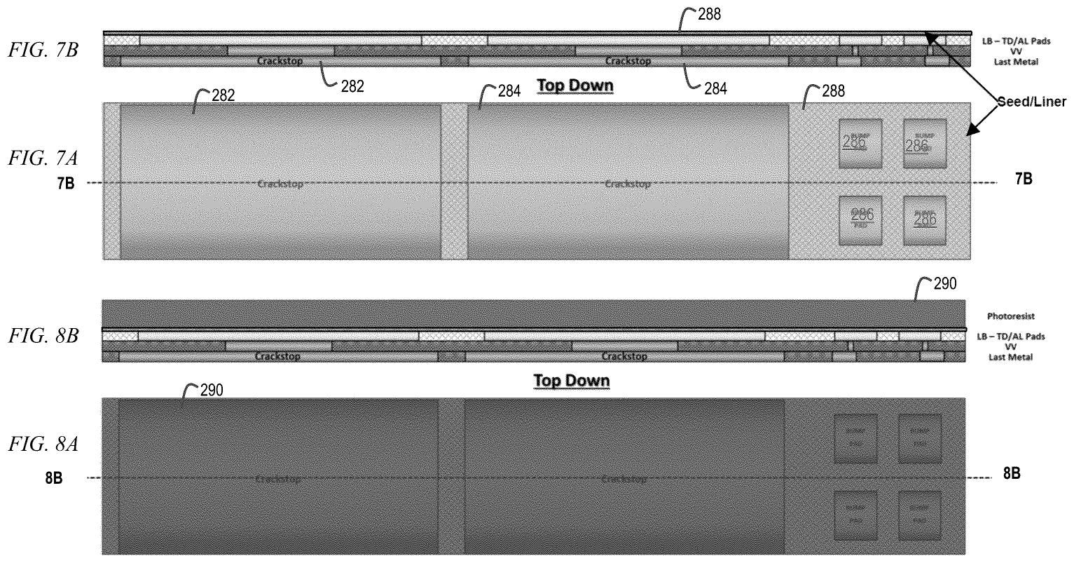

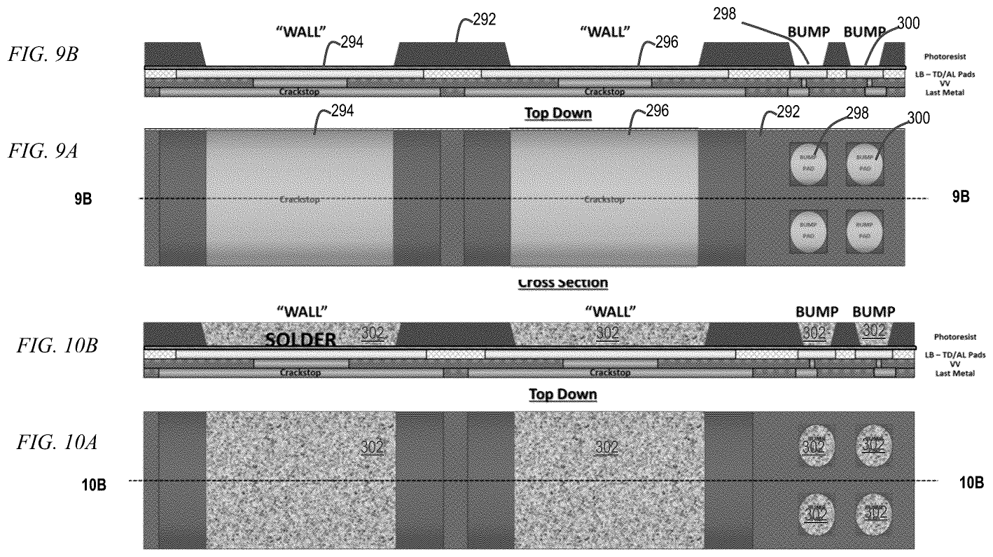

FIGS. 7A-12B are top views and cross section views illustrating a first method for forming metal lines on a semiconductor build for building a unified crackstop structure. Such a structure can be formed at times when the semiconductor build is joined with another semiconductor build having a crackstop structure and metal landing pads thereon for receiving metal lines. FIG. 7A is a top view showing the outline on a semiconductor build 280 having two crackstop structures 282 and 284 and four bump pads 286 underneath a seed layer 288. FIG. 7B shows a cross-section view of 7A along the lines 7B-7B showing the upper layers of semiconductor build 280. FIG. 8A is a top view as shown in FIG. 7A except with a photoresist layer 290 on the top surface. FIG. 8B is a cross-section view of FIG. 8A along the lines 8B-8B. FIG. 9A is a top view as shown in FIG. 8A except with photoresist layer 290 patterned and developed as patterned layer 292. FIG. 9B is a cross-section view of FIG. 9A along the lines 9B-9B showing openings 294, 296, 298 and 300.

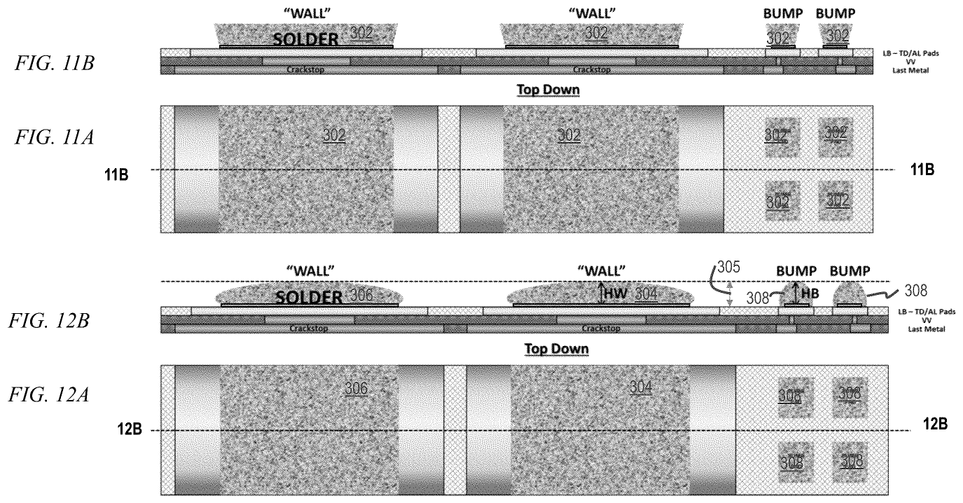

FIG. 10A is a top view as shown in FIG. 9A after solder 302 has been electroplated where the seed layer is exposed. FIG. 10B is a cross-section view of FIG. 10A along the lines 10B-10B. FIG. 11A is a top view as shown in FIG. 10A after the photoresist 290 has been removed. FIG. 11B is a cross-section view of FIG. 11A along the lines 11B-11B showing solder 302. FIG. 12A is a top view of the structure of FIG. 11A after metal reflow-referring also to FIG. 12B showing metal lines 304 and 306 and solder bumps 308 after metal reflow. FIG. 12B is a cross-section view of FIG. 12A along the lines 12B-12B after metal reflow. The height of bumps 306 and 308 is shown by arrow 305.

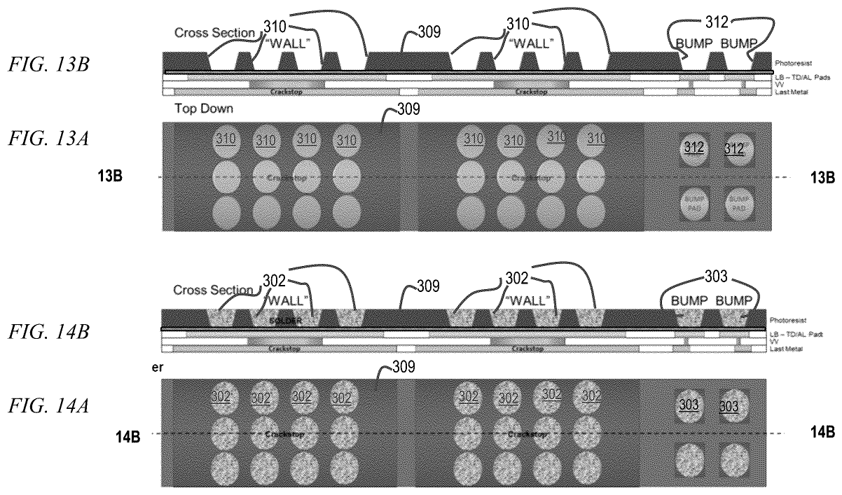

FIGS. 7A-8B and 13A-16B are top views and cross section views illustrating a second method for forming metal lines on a semiconductor build for building a unified crackstop structure (FIGS. 7A-8B are the same for both methods). Such a structure can be formed at times when the semiconductor build is joined with another semiconductor build having a crackstop structure and metal landing pads thereon for receiving metal lines. FIG. 7A is a top view showing the outline on a semiconductor build 280 having two crackstop structures 282 and 284 and four bump pads 286 underneath a seed layer 288. FIG. 7B shows a cross-section view of 7A along the lines 7B-7B showing the upper layers of semiconductor build 280. FIG. 8A is a top view as shown in FIG. 7A except with a photoresist layer 290 on the top surface. FIG. 8B is a cross-section view of FIG. 8A along the lines 8B-8B. FIG. 13A is a top view as shown in FIG. 8A with the photoresist 290 patterned and developed as patterned photoresist 307 forming an array of openings 310 for two metal lines and solder bump openings 312. FIG. 13B is a cross-section view of FIG. 13A along the lines 13B-13B. FIG. 14A is a top view as shown in FIG. 13A except solder 302, 303 has been electroplated where the seed layer is exposed. FIG. 14B is a cross-section view of FIG. 14A along the lines 14B-14B.

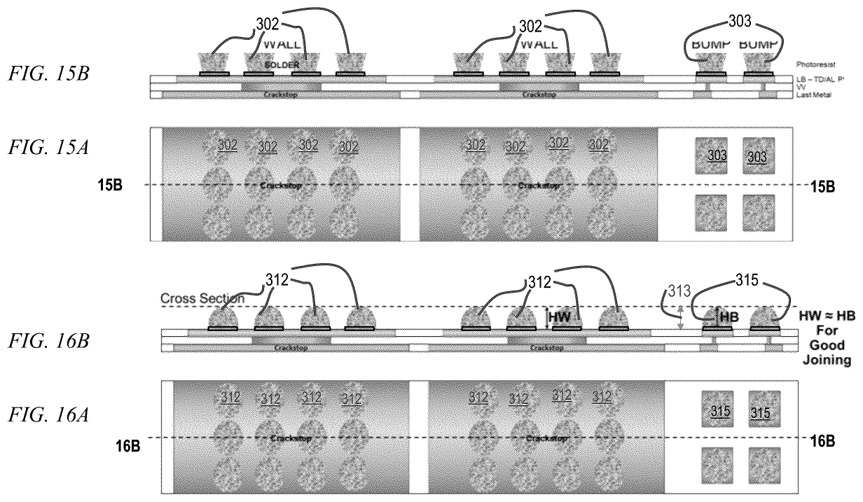

FIG. 15A is a top view as shown in FIG. 14A after patterned photoresist 308 has been removed. FIG. 15B is a cross-section view of FIG. 15A along the lines 15B-15B showing the solder 302 and 303 remaining after the photo resist is removed. FIG. 16A is a top view as shown in FIG. 15A showing two arrays of metal bumps 312 for two metal lines and solder bumps 315 after metal reflow. FIG. 16B is a cross-section view of FIG. 16A along the lines 16B-16B. The height of solder bumps 312 and 315 is shown by arrow 313.

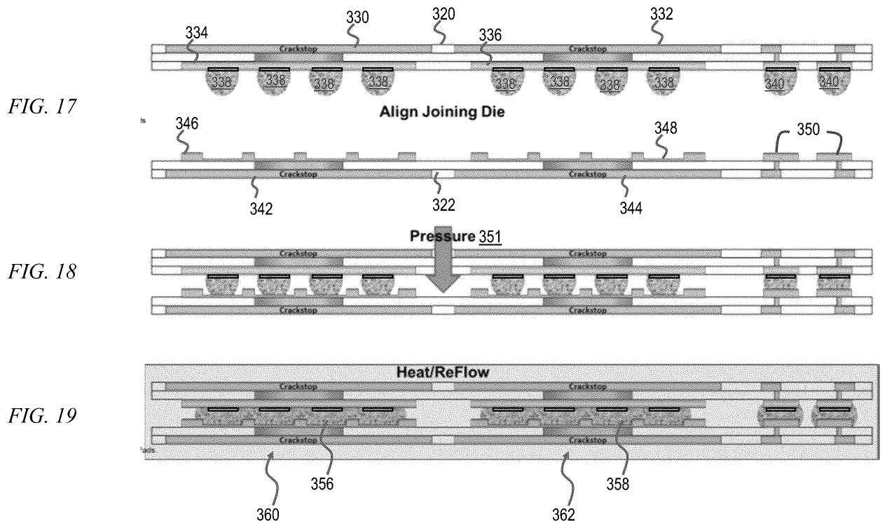

FIGS. 17-19 are cross section views to show steps for joining two semiconductor builds 320 and 322 to form two unified crackstop structures. Semiconductor build 320 has crackstop structures 330 and 332 each contacting a respective landing pad 334 and 336. On landing pads 334 and 336 are solder bumps 338 sized to form a metal line after (i) compression with another semiconductor build and (ii) metal reflow. Solder bumps 340 are for electrical contacts. Semiconductor build 322 has crackstop structures 342 and 344 each contacting a respective landing pad 346 and 348. Landing pads 346 and 348 are shaped to receive solder 338. Contact pads 350 are flat for receiving solder bumps 340.

FIG. 18 is the same as FIG. 17 except semiconductor build 320 is aligned and brought in contact with semiconductor build 322. Pressure 351 is applied to compress solder bumps 338 and 340 a predetermined amount.

FIG. 19 is the same as FIG. 18 except solder bumps have reflowed into metal lines 356 and 358 in response to heat. In FIG. 19 a solid metal wall or line is formed between crackstop structures 330 and 342 to form one unified crackstop structure 360 and a solid metal wall is formed between crackstop structures 332 and 344 to form unified crackstop structure 362. FIG. 19 is a cross section view of metal lines 356 and 358 that extend around a portion of or the entire periphery on landing pads 334 and 336 of semiconductor builds 320 and 322. It is understood that in FIG. 19, metal lines 356 and 358 run in the direction perpendicular to the printed page they are shown on.

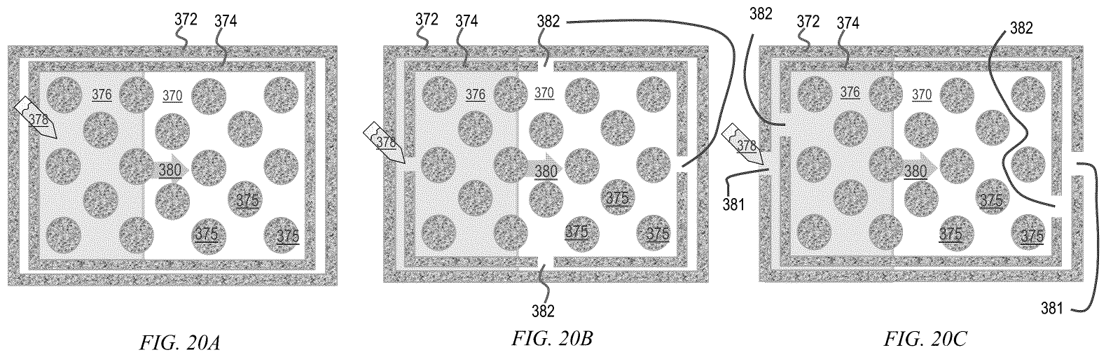

FIG. 20A is a top view of internal surface 370 of a semiconductor build joined with another semiconductor build, not shown, having two continuous unified crackstop structures having respective peripheral metal lines 372 and 374 and solder bumps 375 in the interior 370. A needle 378 is shown inserting dielectric 376 to underfill any voids or spaces. Arrow 380 shows the direction of dielectric flow.

FIG. 20B is the same as FIG. 20A except peripheral metal line 374 has openings 382 to allow dielectric 376 to flow between metal lines 372 and 374 and to all voids and spaces.

FIG. 20C is the same as FIG. 20A except peripheral metal lines 372 and 374 both have respective openings 381 and 382 for inserting and flowing dielectric 376 to all voids and spaces.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a first semiconductor build having a first crackstop structure along a first periphery of said first semiconductor build;
a second semiconductor build having a first crackstop structure along a first periphery of said second semiconductor build; and
a metal line bonded to said first crackstop structure of said first semiconductor build and said first crackstop structure of said second semiconductor build to form a wall between and along at least a portion of said first peripheries of said first and second semiconductor builds such that said crackstop structures are joined together by said metal line.

2. The semiconductor structure of claim 1 wherein said first crackstop structure of said first semiconductor build includes a metal landing pad positioned on said first periphery beneath said metal line.

3. The semiconductor structure of claim 1 wherein said second crackstop structure of said semiconductor build includes a metal landing pad positioned on said second crackstop structure and joined to said metal line.

4. The semiconductor structure of claim 1 wherein said metal line comprises solder.

5. The semiconductor structure of claim 1 wherein said metal line extends along an entire length of said first peripheries.

6. The semiconductor structure of claim 1 wherein said first semiconductor build includes one of a chip, die, wafer and interposer.

7. The semiconductor structure of claim 1 wherein said second semiconductor build includes one of a chip, die, wafer and interposer.

8. The semiconductor structure of claim 1 wherein said semiconductor structure includes underfill.

9. The semiconductor structure of claim 1 wherein said semiconductor structure includes underfill and openings in said metal line to permit said underfill to flow on both sides of said wall.

10. The semiconductor structure of claim 1 wherein:
said first semiconductor build has a second crackstop structure along a second periphery of said first semiconductor build, and
said second semiconductor build has a second crackstop structure along a second periphery of said second semiconductor build,
further comprising a second metal line bonded to said second crackstop structure of said first semiconductor build and said second crackstop structure of said second semiconductor build to form a wall between and along a portion of said second peripheries of said first and second semiconductor build such that said second crackstop structures are joined together by said second metal line.

11. The semiconductor structure of claim 1, wherein:
the metal line is a first metal line;
the first semiconductor build comprises an active chip; and
the second semiconductor build comprises an interposer and has a second crackstop structure along a second periphery of said second semiconductor build;
further comprising:
a third semiconductor build having a first crackstop structure along a first periphery of said third semiconductor build, the third semiconductor structure being an active chip; and
a second metal line bonded to said first crackstop structure of said third semiconductor build and said second crackstop structure of said second semiconductor build to form a wall between and along at least a portion of said first periphery of said third semiconductor build and said second periphery of said second semiconductor build such that said second crackstop structure of said second semiconductor build and said first crackstop structure of said third semiconductor build are joined together by said second metal line.

12. A method for joining two semiconductor builds comprising the steps of
selecting two semiconductor builds, each having a crackstop structure on a periphery thereof,
forming a metal line adjoining one of said crackstop structures on one of said semiconductor builds,
aligning said metal line over said crackstop structure of said other semiconductor build, and
bonding said metal line to said other semiconductor build such that said two semiconductor builds form a rigid structure to resist and/or block at least one of external crack growth, internal cracking, and delamination from thermal cycling warpage.

13. The method of claim 12 wherein said bonding includes thermal compression bonding.

14. The method of claim 12 wherein said step of forming the metal line includes forming a landing pad over said crackstop structure.

15. The method of claim 12 wherein said step of forming the metal line includes forming solder bumps in a line over said crackstop structure.

16. The method of claim 15 wherein said step of forming the metal line includes reflowing said solder bumps such that adjacent solder bumps merge together.
